(19) United States
(12) Patent Application Publication
(10) Pub. No.: US 2012/0326165 A1
(43) Pub. Date: Dec. 27, 2012

(54) HEMT INCLUDING AIN BUFFER LAYER WITH LARGE UNEVENNESS

(75) Inventors: Ken NAKATA, Yokohama-shi (JP); Keiichi YUI, Yokohama-shi (JP)

(73) Assignee: SUMITOMO ELECTRIC INDUSTRIES, LTD., Osaka-shi (JP)

(21) Appl. No.: 13/528,684

(22) Filed: Jun. 20, 2012

(30) Foreign Application Priority Data
Jun. 21, 2011 (JP) 2011-137754

(51) Int. Cl. H01L 29/778; H01L 21/20

(52) U.S. Cl. 257/77; 438/478; 257/E21.09; 257/E29.246

(57) ABSTRACT

A HEMT comprised of nitride semiconductor materials is disclosed. The HEMT includes, on a SiC substrate, a AlN buffer layer, a GaN channel layer, and a AlGaN doped layer. A feature of the HEMT is that the AlN buffer layer is grown on an extraordinary condition of the pressure, and has a large unevenness in a thickness thereof to enhance the release of carriers captured in traps in the substrate back to the channel layer.

### BACKGROUND OF THE INVENTION

1. Field of the Invention

The present invention relates to a semiconductor device, in particular, the invention relates to a semiconductor device made of primarily nitride material.

2. Related Background Arts

A nitride semiconductor has been practically applied in a high-frequency device as a type of, what is called, a high electron mobility transistor (HEMT). A HEMT generally forms a two-dimensional electron gas (2DEG) introduced in the channel layer at the interface against the doped layer, and 2DEG may operate as carriers in the HEMT. However, electrons introduced in 2DEG are sometimes captured in traps caused in the nitride semiconductor material, which reduces the current flowing in the HEMT and degrades the performance thereof. One prior art, Japanese Patent Application published as JP-2006-147663A, has disclosed a technique to suppress the reduction of the current by enhancing the crystal quality of gallium nitride (GaN).

### SUMMARY OF THE INVENTION

One aspect of the present invention relates to a method to form a HEMT using nitride semiconductor materials. The method includes steps of: (a) growing a buffer layer made of AlN on a semiconductor substrate; (b) growing a channel layer made of GaN on the buffer layer; and (c) growing a doped layer made of AlGaN on the channel layer. A feature of the method is that AlN buffer layer is grown under a peculiar pressure exceeding 20 kPa.

The buffer layer grown under such a condition above inherently has unevenness in a thickness thereof, for instance, a difference between a thickest value and a thinnest value exceeds 6 nm even when an average thickness is greater than 6 nm. The buffer layer above described has a feature that an inverse of an average of inverse thickness thereof is less than 10 nm.

Because the buffer layer of the embodiment has such a greater unevenness, carriers captured in traps in the substrate may be easily released back to the channel layer, or to the two dimensional electron gas induced in the interface between the channel layer and the doped layer, which may reduce the reduction of the current flowing the HEMT. The buffer layer is preferably grown under a pressure of 25 kPa, and a temperature exceeding 1000° C.

Another aspect according to an embodiment of the invention relates to an electronic device called as the HEMT. The HEMT of the embodiment comprises an AlN buffer layer, A GaN channel layer, and an AlGaN doped layer, where they are sequentially grown on a SiC substrate. The HEMT of the embodiment has a feature that the AlN buffer layer has an average thickness thereof thinner than 20 nm but a large unevenness of a difference between a thickest thickness and a thinnest thickness is greater than 6 nm.

Because the buffer layer of the embodiment inherently has a portion with smaller thickness, the buffer layer may accelerate carriers captured in traps contained in the SiC substrate to be released back to the channel layer, which may reduce the reduction of the current in the channel layer.

### BRIEF DESCRIPTION OF THE DRAWINGS

The foregoing and other purposes, aspects and advantages will be better understood from the following detailed description of a preferred embodiment of the invention with reference to the drawings, in which:

FIG. 1A shows a cross section of a HEMT according to a comparable example of the present invention, and FIG. 1B shows a band diagram of the HEMT shown in FIG. 1A;

FIG. 2 shows a current variation of the HEMT against a thickness of the buffer layer according to the comparable example of the invention;

FIG. 3A shows a cross section of a HEMT according to an embodiment of the invention, and FIG. 3B schematically shows an unevenness of the surface of the buffer layer measured by the atomic force microscope;

FIG. 4 shows a band diagram of the HEMT according to the first embodiment of the invention; and

FIG. 5 compares the current variation of the HEMT against the average thickness with that of the inverse average thickness.

### DESCRIPTION OF EMBODIMENTS

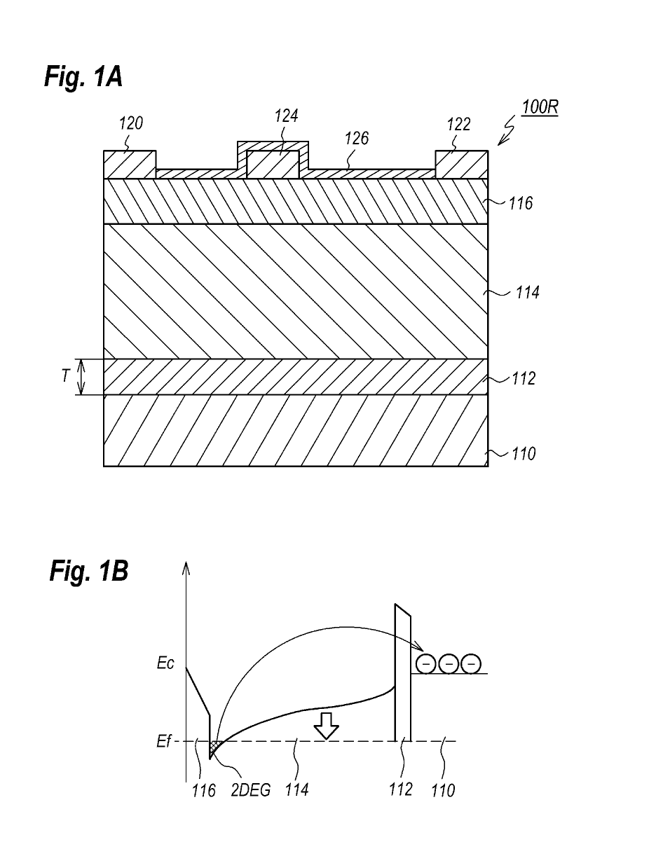

One comparable example will be first described. FIG. 1A shows a cross section of a HEMT 100R according to the comparable example. As shown in FIG. 1A, the HEMT includes a substrate 110 which may be made of silicon carbide (SiC), a buffer layer 112, a channel layer 114, a doped layer 116, electrodes of the source 120, the drain 122, and the gate 124, and a protection layer 126.

The buffer layer 112, which may be made of aluminum nitride (AlN), is grown homogeneously on the substrate 110 under a condition of: source materials of tri-methyl-aluminum (TAM) and ammonia (NH₃), a temperature of 1080° C., and a pressure of 13.3 kPa, where these conditions are quite popular to obtain an AlN layer. A context “homogeneous” means that it is grown so as to have a uniform thickness and has no unevenness greater than a measurement error by the conditions above described. The channel layer 114 grown on the buffer layer 112 may be made of GaN with a thickness of about 1200 nm. The doped layer 116 provided on the channel layer 114 may be made of aluminum gallium nitride (AlGaN) with a thickness of about 20 nm. Ohmic electrodes of the source 120 and the drain 122 are made of stacked metal of titanium and aluminum (Ti/Al), or tantalum and aluminum (Ta/Al), where Ti or Ta is in contact with the doped layer 116. The gate electrode 124 may be also a stacked metal of nickel and aluminum (Ni/Al), where Ni is in contact with the doped layer 116. The gate electrode 124 is formed between two ohmic electrodes of the source 120 and the drain 122. The semiconductor layers from the buffer layer 112 to the doped layer 116 are sequentially grown epitaxially on the substrate 110. Surfaces of the doped layer 116 exposed between the electrodes, 120 to 124, may be protected by an insulating film 126 made of, for instance, silicon nitride (SiN).

The HEMT 100R shown in FIG. 1 may flow a current in 2DEG formed at the interface between the channel layer 114 and the doped layer 116 between two ohmic electrodes, 120 and 122, and this current may be modulated by a bias applied to the gate electrode 124, thus, the HEMT 100R may show an amplifying function.

However, the carriers, namely electrons, in 2DEG are sometimes captured by traps contained in, for instance, the channel layer 14, which reduces the current flowing in 2DEG. Irons (Fe) and/or carbons (C) unintentionally contained in the channel layer 114 may cause traps therein. Reducing the concentration of such impurities to qualify GaN channel layer 114, the traps induced in the channel layer 114 may be decreased. However, even when the channel layer 114 is so qualified, electrons in 2DEG may be further captured by traps in the substrate 110.

FIG. 1B schematically shows the band diagram of the HEMT 100R of the comparable example shown in FIG. 1A. In FIG. 1B, Ef corresponding to a broken line denotes the Fermi level, Ec to the solid line shows the conduction band; and the meshed area denotes 2DEG.

As shown in a thick arrow in FIG. 1B, the conduction band of the channel layer 114 is lowered toward the Fermi energy by the qualification thereof, which may suppress the formation of the traps in the channel layer 114. Because the comparable example applies a wide bandgap material to the buffer layer 112, where aluminum nitride (AlN) is used in the example of FIG. 1B, the buffer layer 112 equivalently operates an a barrier between the channel layer 114 and the substrate 110, namely, the buffer layer 112 may suppress the capture of electrons in 2DEG by the substrate 110. The suppression of the capture may be enhanced by thickening the buffer layer 112.

While, when an excess stress is applied to HEMT 100R, for instance, an extraordinary high voltage is applied thereto, electrons in 2DEG may transcend the buffer layer 112 and captured by the substrate 110 as shown in an arrow appeared in FIG. 1B. The capture of electrons raises the conduction band, which equivalently reduces the carrier concentration in 2DEG to lower the current thereof. Thus, the comparable example of HEMT 100R in the substrate 110 thereof may trap electrons in the channel layer 114 to reduce the usable current thereof.

In order to suppress the reduction of the current in 2DEG, electrons captured in the substrate 110 may be released back to the channel layer 114, which equivalently means that a leak current flowing from the substrate 110 to the channel layer 114 may be increased. Dislocations are caused in the buffer layer 112 due to a difference of the lattice constant between SiC substrate 110 and AlN buffer layer 112, and one type of the leak current, or the release of carriers, accelerated by such dislocations are generally called as Poole-Frenkel effect. The magnitude of the leak current due to the emission of electrons from the traps in the substrate 110 depends on a thickness of the buffer layer 112. A thinner buffer layer may enhance the emission of electrons into the channel layer 114.

One experiment was carried out to investigate the leak current due to the emission from the traps in the substrate. A device under experiment had the layer structure same as those shown in FIG. 1A, but the gate electrode 124 thereof had a stacked metal of nickel and gold (Ni/Au) instead of Ni/Al. The variation of the drain current was measured as varying the thickness of the buffer layer 112. The variation of the drain current was measured under the condition of: a drain current Ids of 10 mA was first induced by applying the drain bias Vds of 50V and adjusting the gate bias; then, a stress was applied under a condition of the gate bias Vgs of −10V and the drain bias Vds of 100V for five minutes; finally, the drain current was measured again under the gate bias Vds of 50V, which was the same conditions with those before the stress above was applied thereto. A ratio of the drain current after and before the stress was applied thereto was investigated as an index of the leak current.

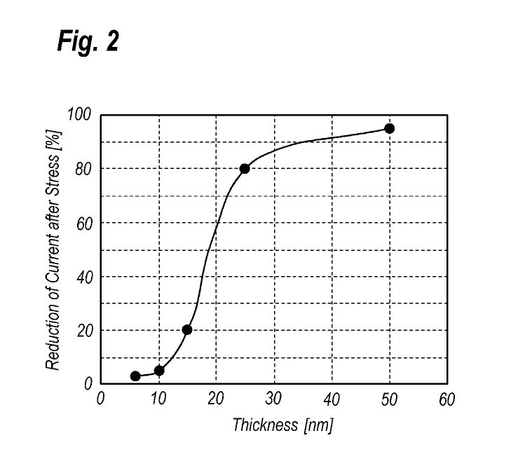

FIG. 2 shows the variation of the drain current against the thickness T of the buffer layer 112. The sample used in this experiment had the buffer layer 112 with substantially no unevenness, which practically and visually verified. The variation 0% means that the drain current was invariant before and after the stress was applied, while, the variation of 100% means the drain current became 0 mA after the stress was applied.

As shown in FIG. 2, the variation of the drain current reduces as the thickness T of the buffer layer 112 becomes thinner. For instance, the variation, or the reduction, of the drain current exceeds 90% when the buffer layer 112 has the thickness T of 50 nm; while, the variation reduces to about 60% for the thickness T of about 20 nm. Similarly, the variation further reduces to 20% at the thickness T of 15 nm, less than 10% for the thickness T of about 10 nm, and becomes about 5% at the thickness T of about 6 nm. Thus, a thinner buffer layer 112 may reduces the reduction of the current flowing in the channel layer by increasing the carriers emitted from the substrate 110 and injected into 2DEG.

However, such a thinner buffer layer 112 is hard to grow, in particular, a buffer layer with a thickness equal to or less than 6 nm is quite hard to grow with good reproducibility. An uneven buffer layer may scatter the performance of the HEMT. Accordingly, a method to form a thinner buffer layer in stable and reproducible compatible with the suppression of the reduction of carriers in 2DEG is inevitable.

Next, some preferred embodiment according to the present invention will be described as referring to drawings.

### First Embodiment

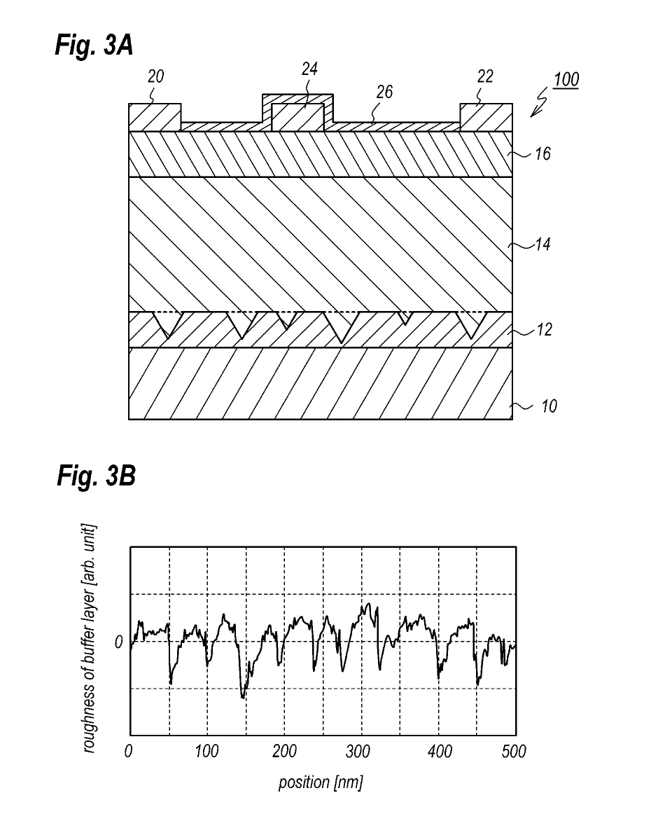

FIG. 3A shows a cross section of a HEMT according to the first embodiment of the invention. Arrangements of the HEMT 100 shown in FIG. 3A same as those shown in FIG. 1 will be omitted in their explanations. The HEMT 100 includes a substrate 10, a buffer layer 12, a channel layer 14, a doped layer 16, electrodes of the source 20, the drain 22, and the gate 24, and a protection film 26, each layers and electrodes are stacked on the substrate 10 in this order.

Specifically, the buffer layer 12 is provided on the substrate 10, the channel layer 14 is stacked on the buffer layer 12, the doped layer 16 is stacked on the channel layer 14; and the electrodes, 20 to 24, are provided on the doped layer 16. Moreover, the buffer layer 12 may be made of aluminum nitride (AlN) and has an uneven top surface. FIG. 3A schematically illustrates the unevenness of the top of the buffer layer 12, whose depths and counts are schematically appeared only for the explanations. A feature of the HEMT 100 shown in FIG. 3A is that the buffer layer 12 is grown at a pressure of 26.6 kPa, which is twice as that for the comparable example of the HEMT 100R shown in FIG. 1A.

The unevenness of the top of the buffer layer 12 was measured by Atomic Force Microscope, which is generally called as AFM. FIG. 3B shows the magnitude of the unevenness in the vertical axis thereof, while, the horizontal axis corresponds to the lateral position relative to a point from which the measurement by the AFM started. As FIG. 3B shows, the top of the buffer layer 12 shows a large unevenness.

The thickness of the buffer layer 12 in a specimen for the AFM measurement was about 9 nm in a thinnest point; while it was 26 nm in a thickest point. In other words, a difference between the thickest and the thinnest was about 17 nm. The “average thickness” may be defined by an average of thicknesses of the buffer layer 12, while, the “inverse average thickness” may be defined as the inverse of an average of the inverse thicknesses. Then, the specimen under the measurement has the buffer layer whose average thickness is about 20 nm, while, the inverse average thickness is about 15 nm, that is, the top of the buffer layer 12 of the present embodiment has relatively large unevenness compared with those of the comparable embodiment shown in FIG. 2.

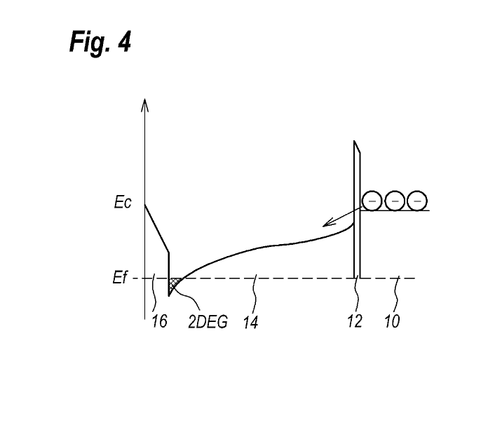

The band structure of the present embodiment will be described. FIG. 4 schematically illustrates the band diagram of the HEMT 100 according to the present embodiment, where FIG. 4 corresponds to a portion where the buffer layer 12 in the thickness thereof is relatively thinner. Comparing the band diagram shown in FIG. 4 with that shown in FIG. 1B, because the buffer layer 12 becomes so thin, carriers captured in the substrate 10, exactly, captured by traps in the substrate 10 are easily released to the channel layer 14 by tunneling the barrier formed by the buffer layer 12 as shown in an arrow in FIG. 4. Accordingly, such a thinner portion effectively operates as a carrier leak path. Releasing the carriers, namely, electrons, to the channel layer 14, the lift up of the conduction band may be suppressed to maintain the carrier concentration in 2DEG in high.

The stress test was carried out as those performed in FIG. 2. That is, the drain current in the channel layer 14 shown in FIG. 3A was compared in before and after the electrical stress of a condition that the gate bias Vg=−10V and the drain bias Vds=100V for 5 minutes was applied thereto. The HEMT 100 shown in FIG. 3A has the drain and source electrodes, 20 and 22, made of stacked metals of Ti/Al, while the gate electrode 24 thereof made of stacked metals of Ni/Au.

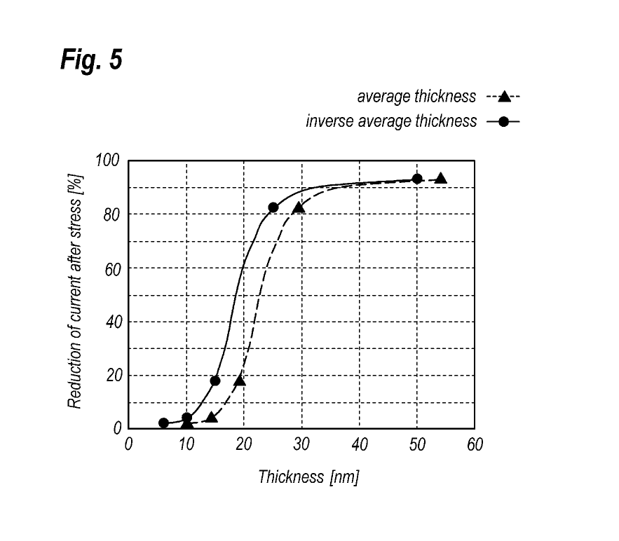

FIG. 5 shows behaviors of the reduction of the current against the average thickness and the inverse average thickness. Referring to FIG. 5, the reduction of the current becomes smaller as the average thickness and the inverse average thickness becomes smaller. Moreover, comparing the reduction of current for respective indices, the inverse average thickness shows a smaller thickness.

For instance, the average thickness of about 25 nm shows the reduction of 60%; while, the inverse average thickness of about 20 nm shows the same reduction. Moreover, when the reduction of the current is about 5%, the average thickness is thinner than 15 nm, while, the inverse average thickness is thinner than 10 nm. The average thickness less than 15 nm, or the inverse average thickness less than 10 nm shows the reduction of the current less than 5%.

Comparing FIG. 5 with FIG. 2, the inverse average thickness in FIG. 5 is necessary to be roughly same as the thickness T in FIG. 2 to get the reduction in the current roughly same to each other. For instance, the thickness T of 15 nm in FIG. 2 and the inverse average thickness of about 15 nm in FIG. 5 to obtain the reduction in the current of about 20%; while, the average thickness of about 20 nm gives the same reduction in the current.

As described, a thinner buffer layer 112 becomes hard to be grown stably. While, in the present embodiment, a same reduction in the current may be obtained under a condition where the inverse average thickness becomes smaller but the average thickness may be larger than the inverse average thickness. For instance, even when the inverse average thickness of 6 nm is selected, the average thickness may be stayed in 10 nm. Thus, the conditions to grow the buffer layer 12 stably may be consistent with the reduction in the current less than 5%.

The HEMT 100 according to the first embodiment includes a substrate 10 made of silicon carbide (SiC), a buffer layer 12 made aluminum nitride (AlN), a channel layer 12 made of gallium nitride (GaN), a doped layer 16 made of AlGaN, and three electrodes of the source 20, the drain 22 and the gate 24. The inverse average thickness of the buffer layer 12 is thinner than 20 nm. Moreover, a conventional growing process may stably grown a buffer layer 12 with a dispersion of the thickness thereof, namely, a difference between the thickest and the thinnest is greater than 6 nm. In other words, a buffer layer with a superior flatness is hard to grow, but a buffer layer 12, which has the reverse average thickness less than 20 nm and the difference between the thickest and the thinnest is greater than 6 nm, may be stably and repeatedly available. A buffer layer 12 with the thickness dispersion, namely, a difference between the thickest and the thinnest, is greater than 10 nm may be further available. In such a buffer layer with relatively larger thickness dispersion, thinner portions of such a buffer layer becomes a current leak path to release carriers captured and trapped in centers in the substrate 10. Thus, the HEMT 100 of the first embodiment may suppress the reduction of the drain current.

The inverse average thickness less than 15 nm may reduce the current reduction less than 20%; the inverse average thickness less than 10 nm results in the current reduction of about 5%. Finally, the inverse average thickness of 5 to 6 nm, the current reduction less than 5% may be available. Thus, making the inverse average thickness thinner, the current reduction may be effectively suppressed, while, an increased average thickness makes it possible to grown the buffer layer 12 stably. Preferably, the average thickness is thicker than 6 nm to grow the layer stably. Thickness dispersion, a difference between the thickest and thinnest thereof, may be, for instance, greater than 12 nm, preferably greater than 15 nm. The buffer layer 12 may have a thickness from 9 to 26 nm, but this thickness is variable.

The channel layer 14 is preferably made of undoped GaN to prevent traps from being induced therein. An undoped GaN may facilitate the capture of electrons in 2DEG by the substrate 10. However, the unevenness of the buffer layer 12 may accelerate the release of the captured electrons, which may effectively suppress the reduction of the drain current.

Next, a process to form the HEMT of the first embodiment will be described. First, a series of semiconductor layers is grown on SiC substrate 10 by, for instance, Metal Organic Chemical Vapor Deposition (MOCVD) technique. The semiconductor layers include the buffer layer, the channel layer, and the doped layer. The table below summarizes the growth conditions of respective layers, 12 to 16.

TABLE 1
Conditions to grow layers

| | | | | |
|---|---|---|---|---|
| Buffer | AlN | Source: | Tri-Methyl-Aluminum | |
| Layer 12 | | | (TMA) | |
| | | | Ammonium (NH₃) | |
| | | Temp.: | 1080° C. | |
| | | Press.: | 26.6 kPa | |
| Channel | GaN | Source: | Tri-Methyl-Gallium | 60 μmol/min |
| Layer 14 | | | (TMG) | |
| | | | NH₃ | 0.9 mol/min |
| | | Temp.: | 1080° C. | |
| | | Press.: | 13.3 kPa | |
| Doped | AlGaN | Source: | TMA, TMG, NH₃ | |
| Layer 16 | | Temp.: | 1080° C. | |
| | | Press.: | 13.3 kPa | |

Because the lattice constant of SiC substrate 10 and that of GaN buffer layer 12 are different, the buffer layer 12 is inherently grown under the Stranski-Krastanov Growth Mode with the island structure as shown in FIG. 3A. When a buffer layer 12 with an even thickness as those of the comparable example is to be obtained, the pressure under which the buffer layer 12 is grown is set to be typically around 13.3 kPa. The buffer layer 12 with an uneven thickness as those of the present embodiment, the pressure may be set in quite high around 26.6 kPa, twice of the conventional value. An uneven AlN layer according to the present embodiment may be grown under a higher pressure preferably over 20 kPa, or further preferably over 25 kPa. Other conditions such as the growth temperature, a flow rate of TMG, those of NH₃, and so on, may be adjustable to obtain an uneven top of AlN buffer layer.

The process may cover the grown semiconductor layers by the first SiN film. Ohmic electrodes of the source and the drain, and the control electrode of the gate are formed by a sequential step of: exposing the surface of the doped layer 16 by removing a portion of the SiN film; and depositing a metal stack of titanium (Ti) and aluminum (Al) on the exposed surface of the doped layer 161; annealing the thus deposited ohmic metal; expositing a portion of the doped layer 16 between two ohmic electrodes by removing the SiN film; depositing another metal stack of nickel (Ni) and gold (Au); and annealing thus deposited gate metal. Finally, covering the ohmic and gate metal by the second SiN film. Thus, the process to manufacture the HEMT 100 may be completed. The second SiN film accompanied with the first SiN film may operate as a protection layer 26. In a modification, the HEMT may provide a cap layer, which may be made of nitride semiconductor material such as GaN, on the doped layer 15, and the electrodes may be formed on this cap layer.

The embodiment described above provides the doped layer made of AlGaN. However, other nitride semiconductor materials may be applicable as the doped layer 16. The nitride semiconductor material is generally regarded as a compound semiconductor material containing nitrogen (N), for instance, InAlN, InGaN, InN, AlInGaN, and so on are known as a nitride semiconductor material. The doped layer 16 may be made of InAlN, AlInGaN and so on.

While several embodiments and variations of the present invention are described in detail herein, it should be apparent that the disclosure and teachings of the present invention will suggest many alternative designs to those skilled in the art.

We claim:

1. A method to form a high electron mobility transistor (HEMT), comprising steps of:
growing a buffer layer made of aluminum nitride (AlN) on a substrate;
growing a channel layer made of a gallium nitride (GaN) on the buffer layer; and
growing a doped layer made of aluminum gallium nitride (AlGaN) on the channel layer,
wherein the AlN buffer layer is grown under a pressure exceeding 20 kPa.

2. The method of claim 1,
wherein the AlN buffer layer is grown under a pressure exceeding 25 kPa.

3. The method of claim 1,
wherein the AlN buffer layer, the GaN channel layer, and the AlGaN doped layer are grown at a temperature exceeding 1000° C.

4. A high electron mobility transistor (HEMT), comprising:
a substrate made of silicon carbide (SiC);
a buffer layer made of aluminum nitride (AlN);
a channel layer made of gallium nitride (GaN); and
a doped layer made of aluminum gallium nitride (AlGaN),
wherein the buffer layer has an average thickness thinner than 20 nm, and a difference between a thickest thickness and a thinnest thickness is greater than 6 nm.

5. The HEMT of claim 4,
wherein the buffer layer has an inverse of an average of inverse thicknesses thereof less than 10 nm.

6. The HEMT of claim 4,
wherein the buffer layer has an average of thicknesses greater than 6 nm.

7. The HEMT of claim 4,
wherein the buffer layer has a difference between a thickset thickness and a thinnest thickness greater than 10 nm.
